(19) United States
(12) Patent Application Publication
(10) Pub. No.: US 2014/0149253 A1
(43) Pub. Date: May 29, 2014

(54) TASKING SYSTEM FOR MANUFACTURING AN ELECTRONIC UNIT, TRADING SYSTEM FOR A CUSTOMIZED ELECTRONIC UNIT, QUALITY CONTROLLING SYSTEM FOR TRADING A CUSTOMIZED ELECTRONIC UNIT AND METHODS THEREOF

(71) Applicant: Microip Inc., Mahe (SC)

(72) Inventors: Hsi-Kuei Yang, Taipei (TW); Chia-Fen Huang, Hsinchu County (TW); Yu-Ju Yeh, Hsinchu County (TW)

(73) Assignee: Microip Inc., Mahe (SC)

(21) Appl. No.: 14/086,990

(22) Filed: Nov. 22, 2013

(30) Foreign Application Priority Data
Nov. 23, 2012 (TW) 101143992

(51) Int. Cl. G06Q 30/06; H01L 25/00; G06F 17/50

(52) U.S. Cl. CPC G06Q 30/0613; G06F 17/5027; H01L 25/50
USPC 705/26.41; 716/106; 438/106

(57) ABSTRACT

A tasking system for manufacturing an electronic unit is provided. The tasking system is connected to a network platform, the electronic unit includes at least a board circuit and an IC chip corresponded to an IC program. The tasking system includes a task assignment side, a first task processing side and a second task processing side. The task assignment side is connected to the network platform for proving a task requesting table and publishes the task requesting table to the network platform, wherein the task requesting table is corresponded to the electronic unit. The first task processing side is connected to the network platform. The first task processing side constructs the IC chip in accordance with the task requesting table. The second task processing side is connected to the network platform, and the second task processing side constructs the board circuit in accordance with the task requesting table.

### RELATED APPLICATIONS

The application claims priority to Taiwan Application Serial Number 101143992, filed on Nov. 23, 2012, which is herein incorporated by reference.

### BACKGROUND

1. Technical Field

The present disclosure relates to a tasking system, a trading system, a quality controlling system and methods thereof, especially relates to a tasking system for manufacturing an electronic unit, a trading system for a customized electronic unit, a quality controlling system for trading a customized electronic unit and methods thereof.

2. Description of Related Art

Conventionally, in constructing and manufacturing of an electronic product a buyer purchases components of the electronic product from venders and assembles the components by itself or through OEM companies to obtain the electronic product. However, in that the components of the most electronic products are in large amount and complicated, the buyer needs to find companies vending for each of the components, and purchases the components with specific specification from the respective companies.

Recently, many companies accept the requirements of the buyer to customize the components of the electronic product. As far as the buyer is concerned, it seems that the efficiency of selecting the specific components can be improved. However, if the orders from the buyer are decreased, the cost on R&D and manufacturing the components for the manufacturing companies will be increased dramatically; moreover, the orders from the buyer may not even be accepted in case of decreased amount of order. In addition, the quality of the electronic product is depended on each of the components, and the quality of the components depends on the design ability and experience of the individual engineer of those manufacture companies. Accordingly, the buyers have to do the search for the manufacturing companies of the respective components of an electronic product, which requires a lot of cost on times. For example, if the buyer wants to acquire an electronic product which includes an IC chip and a related board circuit, the buyer need to search for an IC design company, an IC chip manufacturing company, a circuit design company and a circuit manufacturing company all together in order to assemble and accomplish the complete electronic product.

### SUMMARY

According to one aspect of the present disclosure, a tasking method for manufacturing an electronic unit is provided. The tasking method is applied on a network platform; the electronic unit includes at least an IC chip, the tasking method includes the steps of: provide a task requesting table by a task assignment side, publish the task requesting table to a network platform, wherein the task requesting table is corresponded to the electronic unit; construct the IC chip by a first task processing side in accordance with the task requesting table; manufacture the IC chip by a chip manufacturing side; construct a board circuit for the IC chip by a second task processing side in accordance with the task requesting table; form the electronic unit, wherein the electronic unit comprises the IC chip and the board circuit; and obtain the electronic unit by the task assignment side through the network platform.

In some implementations, a computer program product is provided for loading and executing the aforementioned tasking method.

According to another aspect of the present disclosure, a tasking system for manufacturing an electronic unit is provided. The tasking system is connected to a network platform, the electronic unit includes at least an IC chip and a board circuit, the IC chip is corresponded to an IC program, the tasking system includes a task assignment side, a first task processing side, and a second task processing side. The task assignment side is connected to the network platform for proving a task requesting table, and the task assignment side publishes the task requesting table to the network platform, wherein the task requesting table is corresponded to the electronic unit acquired by the task assignment side. The first task processing side is connected to the network platform. The first task processing side constructs the IC chip in accordance with the task requesting table. The second task processing side is connected to the network platform, and the second task processing side constructs the board circuit in accordance with the task requesting table.

According to still another aspect of the present disclosure, a trading method for a customized electronic unit is provided. The trading method is applied on a network platform. The network platform provides a buyer side and at least a seller side login into the network platform and performs a network trading of the customized electronic unit which includes at least an IC chip. The trading method includes the steps of: provide a task requesting table by the buyer side, and publish the task requesting table to the network platform, wherein the task requesting table is corresponded to the customized electronic unit; receive and apply the task by the first seller side through the network platform in accordance with the task requesting table; design an IC program corresponded to the IC chip by the first seller side in accordance with the task requesting table; upload a chip function specification according to the IC program to the network platform, wherein the chip function specification has a chip price; receive and apply the task by the second buyer side in accordance with the task requesting table if the buyer side accepting the chip price and the chip function specification; construct a board circuit by the second buyer side in accordance with the task requesting table; upload a circuit function specification of the board circuit to the network platform, wherein the circuit function specification has a circuit price; and

if the buyer side accepts the circuit price and the circuit function specification, the buyer side and the seller side trading on the network platform in accordance with the chip price and the circuit price, and the buyer side obtains the customized electronic unit.

In some implementations, a computer program product is provided for loading and executing the aforementioned trading method.

According to further another aspect of the present disclosure, a trading system for a customized electronic unit is provided. The trading system is connected to a network platform and provides a network trading for the customized electronic unit. The customized electronic unit includes at least an IC chip. The IC chip is corresponded to an IC program. The trading system includes a buyer side, a first seller side, a second seller side and a trading module. The buyer side is connected to the network platform for providing a task requesting table and publicizing the task requesting table to the network platform. The task requesting table is corresponded to the customized electronic unit being purchased by the buyer side. The first seller side is connected to the network platform for receiving and applying the task in accordance with the task requesting table. The first seller side includes an IC designing module, a chip function specification, and a first uploading module. The IC designing module designs the IC program of the IC chip in accordance with the task requesting table. The chip function specification is for instructing the function of the IC chip, and the chip function specification has a chip price that being a predetermined price of the IC chip for the buyer side. The first uploading module is connected to the network platform for uploading the chip function specification to the network platform. The second seller side is connected to the network platform for receiving and applying the task in accordance with the task requesting table. The second seller side includes a board circuit constructing, a circuit function specification and a second uploading module. The circuit constructing module is for constructing a board circuit in accordance with the task requesting table. The circuit function specification is for instructing the function of the board circuit, the circuit function specification has a circuit price that being a predetermined price of the board circuit for the buyer side. The second uploading module is connected to the network platform for uploading the circuit function specification to the network platform. The trading module is connected to the network platform for performing a trading of the customized electronic unit between the buyer side and the seller side in accordance with the price.

According to one aspect of the present disclosure, a quality controlling method for trading an electronic unit is provided. The quality controlling method is applied to a network platform. The electronic unit is a customized electronic unit. The customized electronic unit includes at least an IC chip corresponded to an IC program. The quality controlling method includes the steps of: provide a task requesting table by a buyer side, and publish the task requesting table to the network platform, wherein the task requesting table is corresponded to the customized electronic unit being purchased by the buyer side; construct the customized electronic unit by the seller side in accordance with the task requesting table and provide an estimated finish time; judge the customized electronic unit if accomplished within the estimated finish time; if the customized electronic unit fails to be accomplished within the estimated finish time, a manage side of the network platform lowering a rating of the seller side; investigate the customized electronic unit by an investigating module of the network platform; if the customized electronic unit passes the investigation, the investigating module informs the seller side through the network platform that the customized electronic unit has passed the investigation; upload a function specification of the accomplished and investigated customized electronic unit by the seller side, wherein the function specification has a trading price; the buyer side accepts the function specification and the trading price and trades with the seller side through the network platform for obtaining the customized electronic unit.

In some implementations, a computer program product is provided for loading and executing the aforementioned quality controlling method.

According to one aspect of the present disclosure, a quality controlling system for trading an electronic unit is provided. The quality controlling system is connected to a network platform. The electronic unit is a customized electronic unit. The customized electronic unit includes at least an IC chip corresponded to an IC program. The quality controlling system includes a buyer side, a seller side, a time controlling module, a manage side, an investigating module, and a trading module. The buyer side is connected to the network platform for providing and publicizing a task requesting table on the network platform, herein the task requesting table is corresponded to the customized electronic unit being purchased by the buyer side. The seller side is connected to the network platform. The seller side with a rating includes a customized electronic unit constructing module and a function specification. The customized electronic unit constructing module is for constructing the customized electronic unit in accordance with the task requesting table. The function specification is for instructing the function of the customized electronic unit and has a trading price. The time controlling module is connected to the network platform, the time controlling module has an estimated finish time for the customized electronic unit, the seller side assigns the estimated finish time by the time controlling module, and the time controlling module judges if constructing the customized electronic unit being finished or not within the estimated finish time. The manage side is connected to the network platform. The manage side raises or lowers the rating of the seller side according whether constructing the customized electronic unit being finished within the estimated finish time or not. The investigating module is connected to the network platform. The investigating module investigates the customized electronic unit and judges if the customized electronic unit passes the investigation or not, if the customized electronic unit passes the investigation, the investigating module informs the seller side through the network platform. The trading module is connected to the network platform, if the buyer side accepts the function specification and the trading price, the buyer side trades with the seller side through the network platform according to the trading price and the buyer side obtains the customized electronic unit.

### BRIEF DESCRIPTION OF THE DRAWINGS

The disclosure can be more fully understood by reading the following detailed description of the embodiment, with reference made to the accompanying drawings as follows:

FIG. 1 is a schematic diaphragm showing a tasking system according to one embodiment of the present disclosure;

FIG. 2 is a flow chart showing a tasking method according to another embodiment of the present disclosure;

FIG. 3 is a schematic diaphragm showing a trading system according to still another embodiment of the present disclosure;

FIG. 4 is a flow chart showing a trading method for a customized electronic unit according to further another embodiment of the present disclosure;

FIG. 5 is a schematic diaphragm showing a quality controlling system for trading an electronic unit according to one embodiment of the present disclosure; and

FIG. 6 is a flow chart showing a quality controlling method for trading an electronic unit according to one embodiment of the present disclosure.

### DETAILED DESCRIPTION

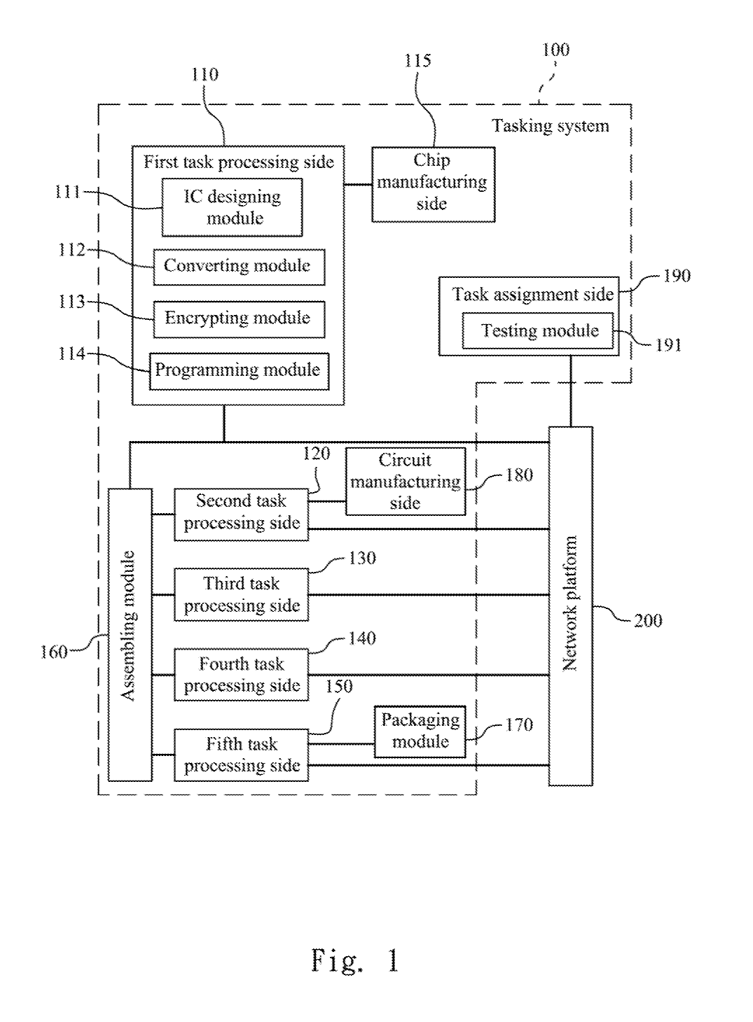

FIG. 1 is a schematic diaphragm showing a tasking system 100 according to one embodiment of the present disclosure. The tasking system 100 for manufacturing an electronic unit is applied on a network environment, and is connected to a network platform 200. The electronic unit at least includes an IC chip and a board circuit. The IC chip is corresponded to an IC program. The IC chip can be a Memory IC chip, a Logic IC chip, a Micro Component IC chip, or an Analog IC chip.

Tasking system 100 includes a first task processing side 110, a chip manufacturing side 115, a second task processing side 120, a third task processing side 130, a fourth task processing side 140, a fifth task processing side 150, an assembling module 160, a packaging module 170, a circuit manufacturing side 180 and a task assignment side 190. The first task processing side 110 includes an IC designing module 111, a converting module 112, an encrypting module 113, and a programming module 114, and the task assignment side 190 includes a testing module 191.

The first task processing side 110, the second task processing side 120, the third task processing side 130, the fourth task processing side 140, the fifth task processing side 150, the assembling module 160 and the task assignment side 190 are all connected to the network platform 200; and the first task processing side 110, the second task processing side 120, the third task processing side 130, the fourth task processing side 140, the fifth task processing side 150 are all connected to the assembling module 160.

The circuit manufacturing side 180 and the packaging module 170 are connected to the second task processing side 120 and the fifth task processing side 150 respectively, and the chip manufacturing side 115 is connected to the first task processing side 110.

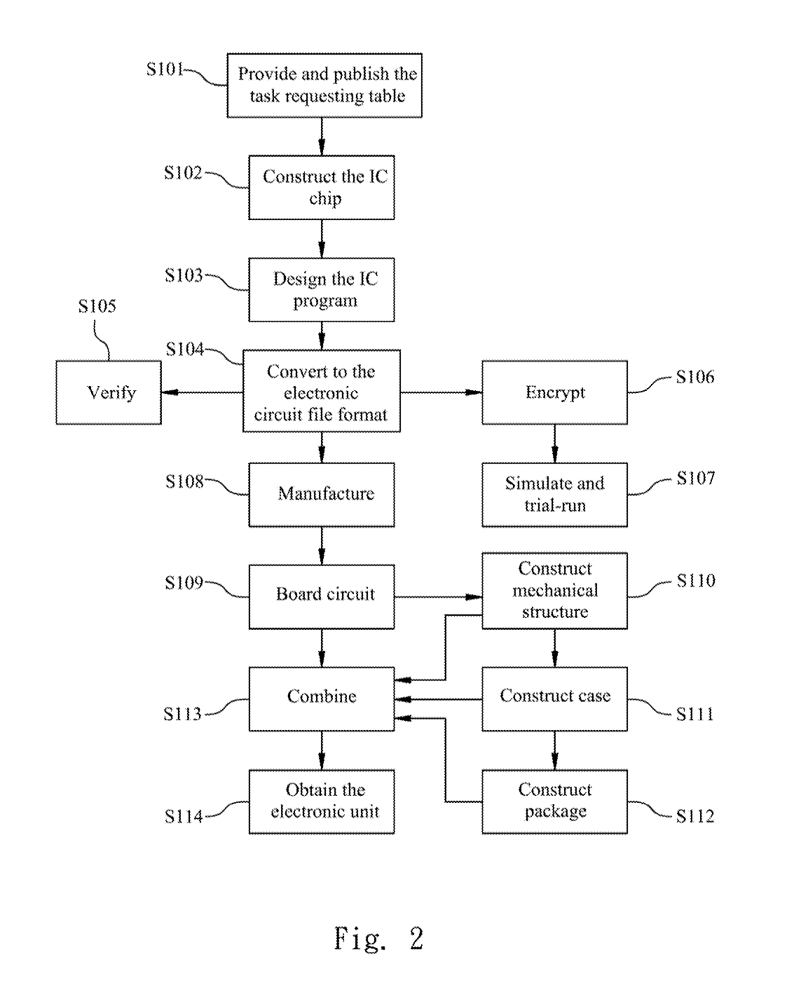

FIG. 2 is a flow chart showing a tasking method according to another embodiment of the present disclosure. The tasking method includes the following steps:

In S101 provide a task requesting table by the task assignment side 190 and publish the task requesting table to the network platform 200, wherein the task requesting table is corresponded to the electronic unit requested by the task assignment side 90.

In S102, the first task processing side 110 browses the task requesting table from the task assignment side 190 on the network platform 200; and the first task processing side 110 receives the task and constructs an IC chip of the electronic unit in accordance with the task requesting table.

In S103, design an IC program of the IC chip by the IC designing module 111 in accordance with the task requesting table.

In S104, convert the IC program to an electronic circuit file format by the converting module 112 of the first task processing side 110 after the IC program is designed completely.

The electronic circuit file format can be programmed to a programmable logic chip in order to perform verification for the IC program in S105. The electronic circuit file format can be encrypted to an encrypted electronic circuit file format by the encrypting module 113 of the first task processing side 110 in S106, and then in S107, simulate and trial-run the encrypted electronic circuit file format by the testing module 191 of the task assignment side 190.

After the simulation and trial-run, in S108, the first task processing side 110 provides the electronic circuit file format to the chip manufacturing side 115 to manufacture an IC chip.

The electronic circuit file format converted from S104 can bypass the verifying process in S105, the encrypting process in S106 or the simulating and trial-running process in S107, and goes to manufacturing process in S108, thus the IC chip is manufactured by the chip manufacturing side 115 directly. If the first task processing side 110 has enough ability on manufacturing the IC chip itself, then can bypass the chip manufacturing side 115, or the first task processing side 110 can be a chip manufacturing side 115.

The aforementioned programmable logic chip, for example, can be a FPGA chip or a CPLD chip, etc. The programmable logic chip can be referred as a kind of logic IC chip.

The IC program can be designed by using a HDL (Hardware Description Language), such as Verilog or VHDL, etc. There is no limitation on the programmable logic chip and the IC program.

In S109, construct and design a board circuit by the second task processing side 120 in accordance with the task requesting table, and manufacture the board circuit by the circuit manufacturing side 180 connected to the second task processing side 120. If the second task processing side 120 has enough ability on manufacturing the board circuit itself, then can bypass the circuit manufacturing side 180.

In S110, when a mechanical structure of the electronic unit is required, the third task processing side 130 receives the task by the network platform 200, and constructs and designs the mechanical structure in accordance with the task requesting table.

In S111, when a case of the electronic unit is required, the fourth task processing side 140 receives the task by the network platform 200, and constructs and designs the case in accordance with the task requesting table.

In S112, when a package of the electronic unit is required, the fourth task processing side 140 receives the task by the network platform 200, and constructs and designs the package in accordance with the task requesting table.

In S113, combine the IC chip, the board circuit, the mechanical structure and the case into a complete electronic unit by the assembling module 160 in accordance with the task requesting table, and packaging the electronic unit by the packaging module 170, and the task assignment 190 can obtain the electronic unit through S114.

If the task requesting table doesn't contain requirements on the mechanical structure, the case and the package, the IC chip and the board circuit manufactured by S108 and S109 can be combined to form an electronic unit in S113, and then the electronic unit can be obtained for a task assignment side 190 in S114.

In detail, whether the flow goes to S110, S111 or S112 or not is depended on the task requesting table. For example, if the requirements on the task requesting table are only an IC chip, a board circuit and a mechanical structure, then S111 and S112 can be bypassed. The flow can go to S113, and an electronic unit can be combined through the assembling module 160 in accordance with the task requesting table, and then the electronic unit can be obtained by the task assignment side 190 through S114.

The aforementioned tasking method can be applied to a trading of the electronic unit with a buying price and a selling price.

The aforementioned tasking method can be implemented by an encoding system readable by a computer, and can be stored in a recording media readable by the computer. The recording media readable by the computer can be any kinds of products that a data readable by the computer can be stored within. For example, the recording media can be a magnetic storage media such as ROM, soft disk, hard disk, portable disk or SSD, etc.; or can be an optical storage media, such as an optical ROM or an optical disk, etc.; or can be a carrier wave such as a data signal transmitting on the Internet. Moreover, the recording media readable by the computer can be distributed on the computer systems connected to the network, and can be stored in a distribution mode, and can execute the encoding media readable by the computer.

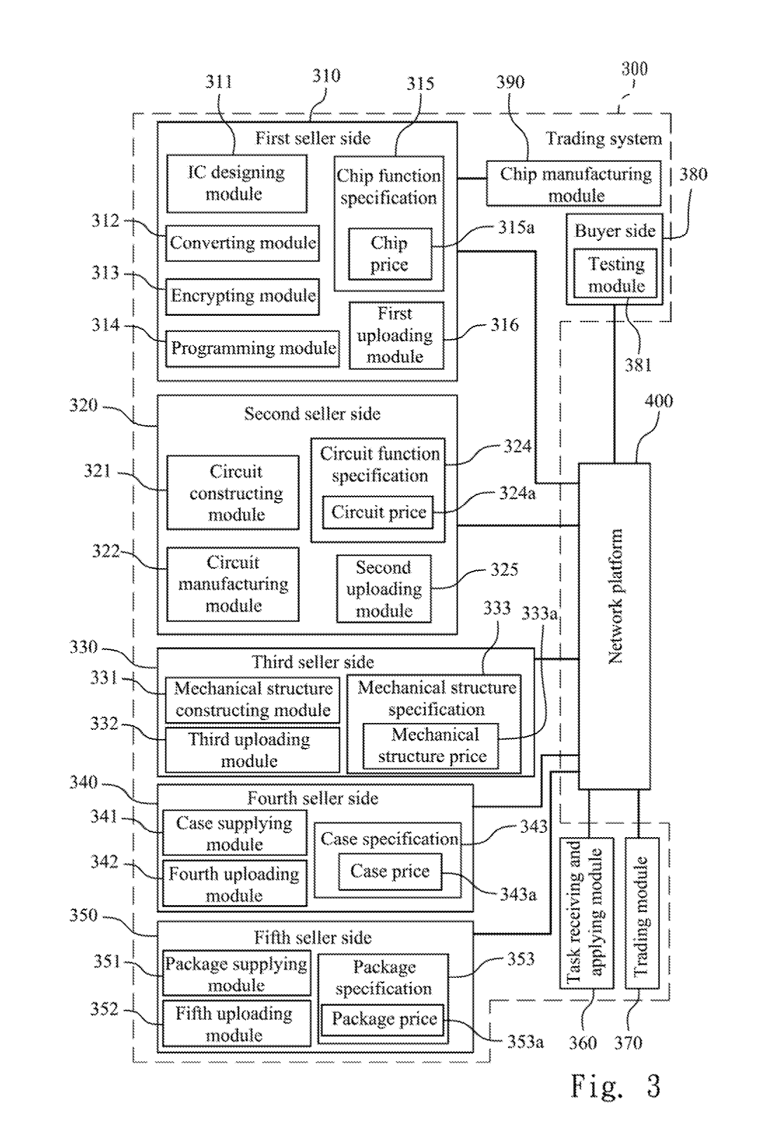

FIG. 3 is a schematic diaphragm showing a trading system according to still another embodiment of the present disclosure. The trading system 300 for a customized electronic unit is applied on the network environment, and is connected to a network platform 400. The customized electronic unit at least includes an IC chip. The IC chip is corresponded to an IC program; and the IC chip can be a Memory IC chip, a Logic IC chip, a Micro Component IC chip, or an Analog IC chip.

The trading system 300 for a customized electronic unit includes a first seller side 310, a second seller side 320, a third seller side 330, a fourth seller side 340, a fifth seller side 350, a task receiving and applying module 360, a trading module 370, a chip manufacturing module 390 and a buyer side 380. The first seller side 310, the second seller side 320, the third seller side 330, the fourth seller side 340, the fifth seller side 350, the task receiving and applying module 360, the trading module 370 and the buyer side 380 are all connected to the network platform 400. The chip manufacturing module 390 is connected to the first seller side 310.

The first seller side 310 includes an IC designing module 311, a converting module 312, an encrypting module 313, a programming module 314, a chip function specification 315 with a chip price 315a and a first uploading module 316.

The second seller side 320 includes a circuit constructing module 321, a circuit manufacturing module 322, a circuit function specification 324 with a circuit price 324a and a second uploading module 325.

The third seller side 330 includes a mechanical structure constructing module 331, a third uploading module 332 and a mechanical structure specification 333 with a mechanical structure price 333a.

The fourth seller side 340 includes a case supplying module 341, a fourth uploading module 342 and a case specification 343 with a case price 343a.

The fifth serer side 350 includes a package supplying module 351, a fifth uploading module 352 and a package specification 353 with a package price 353a.

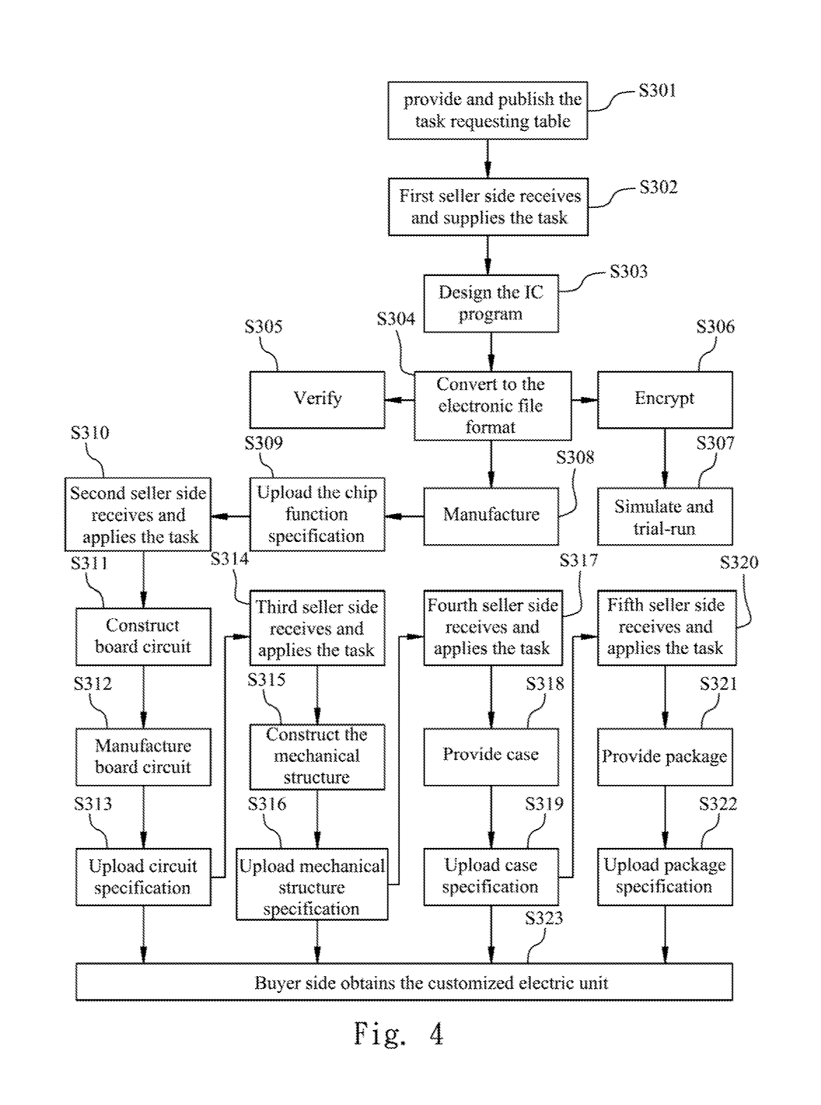

FIG. 4 is a flow chart showing a trading method for a customized electronic unit according to further another embodiment of the present disclosure. The trading method for a customized electronic unit is applied on a network environment, thus a buyer side and at least a seller side can login to the trading system 300 and trade the customized electronic unit on the network platform 400 connected to the trading system 300. The customized electronic unit includes at least an IC chip.

First, in S301, the buyer side 380 provides a task requesting table for the customized electronic unit. The task requesting table can contain a function, an appearance or an effect of the customized electronic unit. The customized electronic unit can be a portable disk, a mp3 Walkman, a robot or a toy car, etc. In S302, after the buyer side 380 publishes the task requesting table on the network platform 400, the first seller side 310 browses the task requesting table and receives and applies the task through the task receiving and applying module 360 connected to the network platform 400.

In S303, the first seller side 310 designs an IC program of the IC chip by the IC designing module 311 in accordance with the task requesting table.

In S304, convert the IC program to an electronic circuit file format by the converting module 312 after the IC program is designed completely.

The electronic circuit file format can be programmed to a programmable logic chip in order to perform verification for the IC program in S305. The electronic circuit file format can be encrypted to an encrypted electronic circuit file format by the encrypting module 313 of the first seller side 310 in S306, and then in S307, simulate and trial-run the encrypted electronic circuit file format by the testing module 381 of the buyer side 380.

After the simulation and trial-run, in S308, the first seller side 310 provides the electronic circuit file format to the chip manufacturing module 390 to manufacture the IC chip.

However, the manufacturing of the IC chip is not limited to the aforementioned steps.

For example, if the first seller side 310 has enough ability on manufacturing the IC chip itself, then can bypass the chip manufacturing module 390.

The electronic circuit file format converted from S304 can bypass the verifying process in S305, the encrypting process in S306 or the simulating and trial-running process in S307, and goes to the manufacturing process in S308.

The aforementioned programmable logic chip, for example, can be a FPGA chip or a CPLD chip, etc. The programmable logic chip can be referred as a kind of logic IC chip.

The IC program can be designed by using a HDL (Hardware Description Language), such as Verilog or VHDL, etc. There is no limitation on the programmable logic chip and the IC program.

In S309, after the IC program is designed completely by the IC designing module 311, the first uploading module 316 uploads the chip function specification 315 for the IC chip and/or the IC program on the network platform 400, the chip function specification 315 has the chip price 315a determined by the first seller side 310.

If the buyer side 380 accepts the chip price 315a and the chip function specification 315, then goes to S310, the second seller side 320 receives the task through the task receiving and applying module 360 of the network platform 400.

In S311, the circuit constructing module 321 of the second seller side 320 constructs and designs the board circuit. After finishing constructing the board circuit, in S312, the second seller side 320 manufactures the board circuit by the circuit manufacturing module 322.

In S313, after the board circuit is manufactured, the second uploading module 325 uploads a circuit function specification 324 on the network platform 400. The circuit function specification 324 has a circuit price 324a determined by the second seller side 320.

The manufacturing process of the board circuit is not limited, for example, if the second seller side 320 has enough ability to manufacture the board circuit, the circuit manufacturing module 322 can be bypassed.

If the buyer side 380 accepts the circuit price 324a and the circuit function specification 324, and the task requesting table published by the buyer side 380 includes requirement on the mechanical structure of the customized electronic unit, then goes to S314, the third seller side 330 receives the task through the task receiving and applying module 360 of the network platform 400.

In S315, after the third seller side 330 receives the task, the mechanical structure is constructed by the mechanical structure constructing module 331 in accordance with the task requesting table.

In S316, the third uploading module 332 uploads a mechanical structure specification 333 to the network platform 400. The mechanical structure specification 333 has a mechanical structure price 333a pre-determined by the third seller side 330.

If the buyer side 380 accepts the mechanical structure price 333a and the mechanical structure specification 333, and the task requesting table published by the buyer side 380 includes requirement on the case of the customized electronic unit, then goes to S317, the fourth seller side 340 receives the task through the task receiving and applying module 360 of the network platform 400.

In S318, after the fourth seller side 340 receives the task, the case is provided. In one example, the case supplying module 341 constructs the case in accordance with the task requesting table.

In S319, the fourth uploading module 342 uploads a case specification 343 to the network platform 400. The case specification 343 has a case price 343a pre-determined by the fourth seller side 340.

If the buyer side 380 accepts the case price 343a and the case specification 343, and the task requesting table published by the buyer side 380 includes requirement on the package of the customized electronic unit, then goes to S320, the fifth seller side 350 receives the task through the task receiving and applying module 360 of the network platform 400.

In S321, after the fifth seller side 350 receives the task, a package is provided. In one example, the package supplying module 351 constructs the package in accordance with the task requesting table.

In S322, the fifth uploading module 352 uploads a package specification 353 to the network platform 400. The package specification 353 has a package price 353a pre-determined by the fifth seller side 350.

In S323, the IC chip, the board circuit, the package, the mechanical structure and the case are assembled to form the customized electronic unit, and the buyer side 380, the first seller side 310, the second seller side 320, the third seller side 330, the fourth seller side 340, and the fifth seller side 350 trade the customized electronic unit by the trading module 370 in accordance with the chip price 315a, the circuit price 324a the mechanical structure price 333a, the case price 343a and the package price 353a.

If the task requesting table doesn't contain requirements on the mechanical structure, the case and the package, the IC chip and the board circuit manufactured by S308 and S312 can be combined to form the customized electronic unit in S323, and then the customized electronic unit can be obtained for a buyer side 380.

In other word, whether the flow goes to S314, S317 or S320 or not is depended on the task requesting table. For example, if the requirements on the task requesting table are only an IC chip, a board circuit and a mechanical structure, then S317 and S320 can be bypassed. The flow can go through S314, S315, and S316 to S323 where an electronic unit can be combined in accordance with the task requesting table, and then can be obtained by the buyer side 380.

The aforementioned tasking method can be implemented through an encoding system readable by a computer, and can be stored in a recording media readable by the computer. The recording media readable by the computer can be any kinds of products that a data readable by the computer can be stored within. For example, the recording media can be a magnetic storage media such as ROM, soft disk, hard disk, portable disk or SSD, etc.; or can be an optical storage media, such as an optical ROM or an optical disk, etc.; or can be a carrier wave, such as a data signal transmitting on the Internet. Moreover, the recording media readable by the computer can be distributed on the computer systems connected to the network, and can be stored in a distribution mode, and can execute the encoding media readable by the computer.

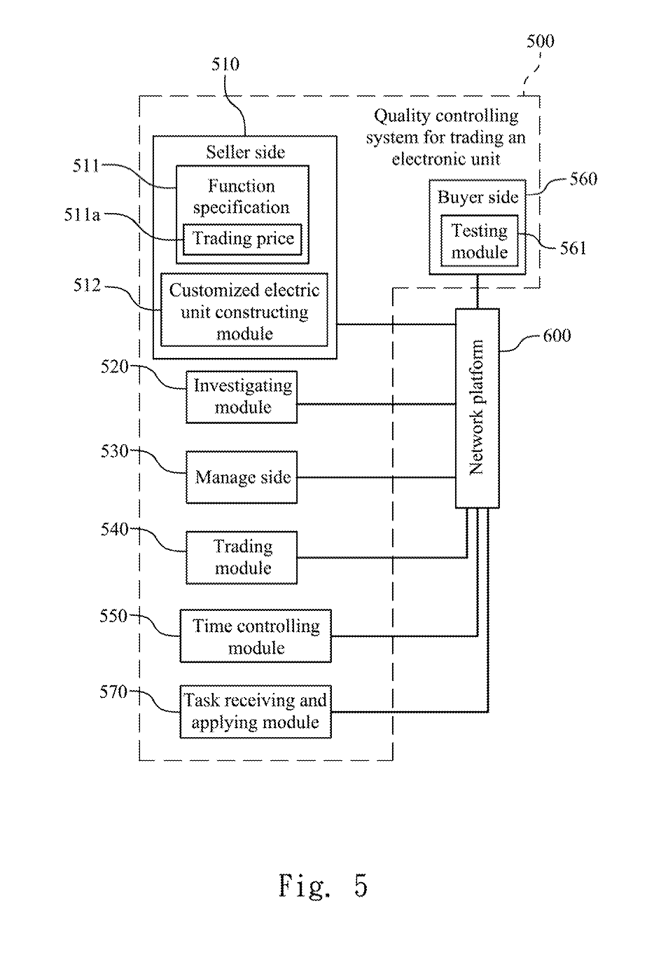

FIG. 5 is a schematic diaphragm showing a quality controlling system for trading an electronic unit according to one embodiment of the present disclosure. The quality controlling system 500 for trading an electronic unit is connected to a network platform 600. The electronic unit is a customized electronic unit. The customized electronic unit at least includes an IC chip, and can also include one of a board circuit, a mechanical structure, a case and a package as well. The IC chip is corresponded to an IC program. The quality controlling system 500 for trading an electronic unit includes a seller side 510, an investigating module 520, a manage side 530, a trading module 540, a time controlling module 550, a task receiving and applying module 570 and a buyer side 560. The seller side 510, the investigating module 520, the manage side 530, the trading module 540, the time controlling module 550, the task receiving and applying module 570 and the buyer side 560 are all connected to the network platform 600. The seller side 510 includes a customized electronic unit constructing module 512, and a function specification 511 having a trading price 511a. The buyer side 560 includes a testing module 561.

The aforementioned IC chip can be a Memory IC chip, a Logic IC chip, a Micro Component IC chip or an Analog IC chip, etc.

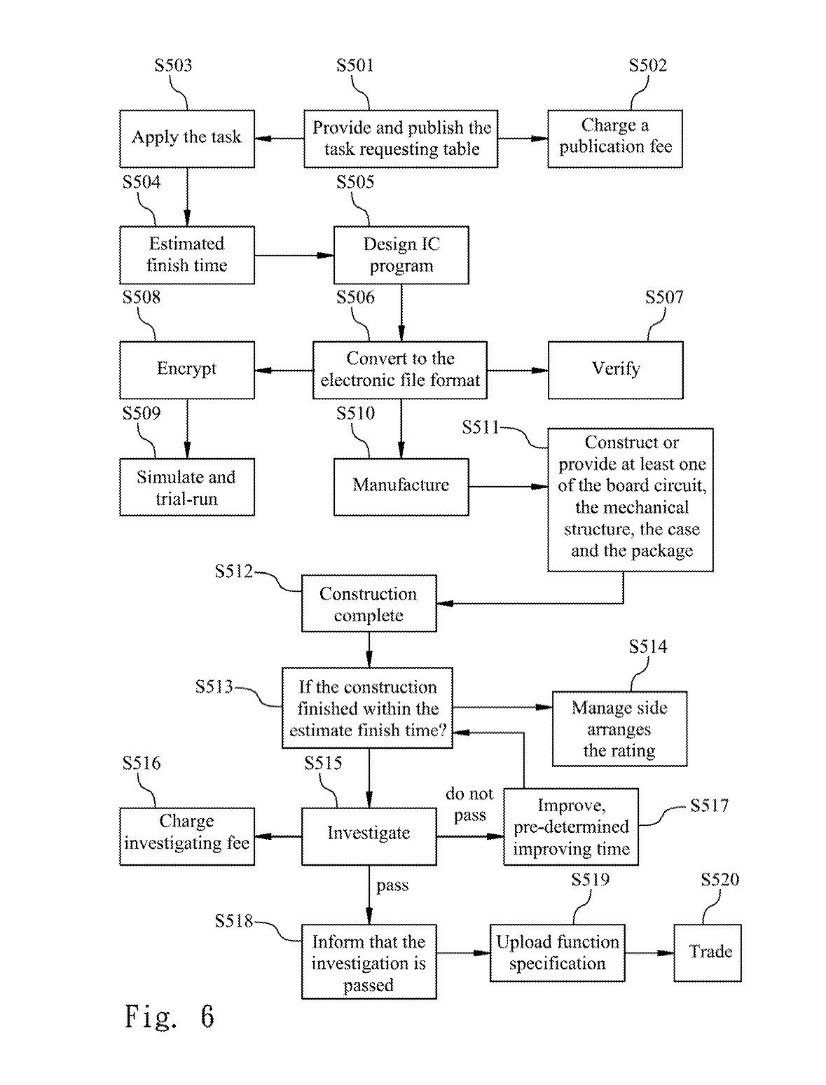

FIG. 6 is a flow chart showing a quality controlling method for trading an electronic unit according to one embodiment of the present disclosure. The quality controlling method includes the following steps:

In S501, the buyer side 560 provides a task requesting table for the customized electronic unit and publishes it to a network platform 600. The task requesting table is corresponded to the customized electronic unit, and can contain a function, an appearance or an effect of the customized electronic unit. The customized electronic unit can be a portable disk, a mp3 Walkman, a robot or a toy car, etc.

In S502, after the buyer side 560 publishes the task requesting table to the network platform 600, the network platform 600 can charge or discharge a publication fee to the buyer side 560. When the task requesting table has been published, in S503, the seller side 510 can browse the task requesting table through the network platform 600, and apply the task by the task receiving and applying module 570.

After receiving the task, in S504, the seller side 510 evaluates an estimated finish time on constructing, designing and manufacturing the customized electronic unit in accordance with the task requesting table provided by the buyer side 560, and registers the estimated finish time by the time controlling module 550 to the network platform 600. Then, the seller side 510 performs the construction of the customized electronic unit.

In S505, the seller side 510 designs an IC program of the IC chip by the customized electronic unit constructing module 512 in accordance with the task requesting table.

In S506, convert the IC program to an electronic circuit file format by the customized electronic unit constructing module 512 after the IC program is designed completely.

The electronic circuit file format can be programmed to a programmable logic chip in order to perform verification for the IC program in S507. The electronic circuit file format can be encrypted to an encrypted electronic circuit file format by the customized electronic unit constructing module 512 in S508, and then in S509, simulate and trial-run the encrypted electronic circuit file format by the testing module 561.

The electronic circuit file format converted from S506 can bypass the verifying process in S507, the encrypting process in S508 or the simulating and trial-running process in S509, and goes to S510, thus the seller side 510 can manufacture the IC chip in accordance with the converted electronic circuit file format.

In S511, the customized electronic unit constructing module 512 constructs or provides at least one of a board circuit, a mechanical structure, a case and a package.

In S512, the customized electronic unit is constructed by the seller side 510, and in S513, the time controlling module 550 judges if the customized electronic unit is constructed completely within the estimated finish time.

In S514, if the seller side 510 doesn't finish within the estimated finish time, the manage side 530 lowers a rating of the seller side 510. If the seller side 510 finishes constructing the customized electronic unit within the estimated finish time, the manage side 530 raises the rating of the seller side 510.

In S515, the investigating module 520 investigates the customized electronic unit constructed by the seller side 510, for example, a quality of the customized electronic unit, and judges if the customized electronic unit passes the investigation. In S516, the network platform 600 can charge or discharge an investigating fee to the seller side 510.

In S517, if the customized electronic unit doesn't pass the investigation, the manage side 530 can inform the seller side 510 to improve, or, back to S517, perform a re-investigation after the seller side 510 finishing improving the customized electronic unit within a pre-determined improving time.

In S518, if the customized electronic unit passes the investigation, the investigating module 520 informs this information to the seller side 510 through the network platform 600, and in S519, the seller side 510 uploads a function specification 511 with a trading price 511a.

In S520, the buyer side 560 accepts the function specification 511 and the trading price 511a, and trades with the seller side 510 in accordance with the trading price 511a, and then the buyer side 560 can obtain the customized electronic unit.

The aforementioned programmable logic chip, for example, can be a FPGA chip or a CPLD chip, etc. The programmable logic chip can be referred as a kind of logic IC chip.

The IC program can be designed by using a HDL (Hardware Description Language), such as Verilog or VHDL, etc. There is no limitation on the programmable logic chip and the IC program.

The aforementioned tasking method can be implemented through an encoding system readable by a computer, and can be stored in a recording media readable by the computer. The recording media readable by the computer can be any kinds of products that a data readable by the computer can be stored within. For example, the recording media can be a magnetic storage media such as ROM, soft disk, hard disk, portable disk or SSD, etc.; or can be an optical storage media, such as an optical ROM or an optical disk, etc.; or can be a carrier wave, such as a data signal transmitting on the Internet. Moreover, the recording media readable by the computer can be distributed on the computer systems connected to the network, and can be stored in a distribution mode, and can execute the encoding media readable by the computer.

From above, the tasking method and trading method for manufacturing a customized electronic unit, and the quality controlling method for trading an electronic unit are provided in the present disclosure. Those methods can satisfy demands of the buyer (referred to the buyer side in the embodiment above) on obtaining the customized electronic unit, and can dramatically reduce the cost of time for the buyer side in searching for vendors. The present disclosure has advantages follows:

1. When the buyer proposes a demand on the customized electronic unit, the one who can satisfy the demands is not only an IC design company or a manufacturing company, etc., but also can be a designer who works at home. For example, an IC designer for a programmable logic chip and the effect on the network can be fully used.

2. The aforementioned IC designer is not necessarily required working in a real IC design company. The designer can receive the task at home through the network, and performs the customized request by the buyer side, in this way; the buyer can get the maximum benefit.

3. The aforementioned IC designer can be worldwide IC designers on the Internet. The buyer side provides the task requesting table to the network platform. Through the network platform, the worldwide IC designers can perform discussions and technical exchanges in accordance with the task requesting table, thus leading to positive competitions. Thus, the electronic product can be developed rapidly with highest quality. For example, if the customized electronic unit required by the buyer side includes a chip, and the buyer side only searching one company for designing the chip. The company is may not be the most suitable one for designing the chip, thereby leading a bad quality of the chip. Furthermore, software or firmware involved with the chip for the electronic unit can also be provided through the network platform, thus high quality software or firmware can be obtained from worldwide programmers. There is no limitation on the tasking system, trading system, and quality controlling system and methods thereof of the present disclosure, hardware such as electronic products and software/firmware for the electronic products can be obtained by the systems or methods of the present disclosure.

4. The process on manufacturing the customized electronic unit can be simplified. The buyer side only needs to provide a request on manufacturing the customized electronic unit to the network platform; finally they can obtain the customized electronic unit rapidly with highest quality. During the manufacturing process, investigating mechanism will execute on each station of the manufacturing process, thus the quality of the customized electronic unit will be controlled, and the buyer side can easily purchase and obtain the customized electronic unit.

5. The requests on the customized electronic unit are determined by the buyer side, and the price is codetermined by the buyer side and the seller side.

The buyer side can be a person or a privately owned enterprise. For the privately owned enterprise, the customized electronic unit or electronic product can be a good gift. For example, if the customized electronic unit is a MP3 Walkman, the functions, the appearances and the package of the MP3 Walkman can be customized. The final product can totally meets the requirements of the buyer side.

It will be apparent to those skilled in the art that various modifications and variations can be made to the structure of the present disclosure without departing from the scope or spirit of the disclosure. In view of the foregoing, it is intended that the present disclosure covers modifications and variations of this disclosure provided they fall within the scope of the following claims.

What is claimed is:

1. A tasking method for manufacturing an electronic unit, the tasking method being applied on a network platform and the electronic unit with at least an IC chip, the tasking method comprising:
providing a task requesting table by a task assignment side, and publicizing the task requesting table to a network platform, wherein the task requesting table is corresponded to the electronic unit;
constructing the IC chip by a first task processing side in accordance with the task requesting table;
manufacturing the IC chip by a chip manufacturing side;
constructing a board circuit for the IC chip by a second task processing side in accordance with the task requesting table;
forming the electronic unit, wherein the electronic unit comprises the IC chip and the board circuit; and
obtaining the electronic unit by the task assignment side through the network platform.

2. The tasking method of claim 1, wherein constructing the IC chip by the first task processing side is designing an IC program of the IC chip in accordance with the task requesting table.

3. The tasking method of claim 2, wherein the IC program is designed by using a HDL, wherein the HDL comprises a Verilog or a VHDL.

4. The tasking method of claim 2, further comprising:
converting the IC program to an electronic circuit file format by a converting module.

5. The tasking method of claim 4, further comprising:
programming the electronic circuit file format to a programmable logic chip by the first task processing side in order to verify the IC program.

6. The tasking method of claim 5, wherein the programmable logic chip comprises a FPGA chip or a CPLD chip.

7. The tasking method of claim 4, wherein the IC chip is manufactured by the chip manufacturing side in accordance with the electronic circuit file format converted from the IC program.

8. The tasking method of claim 4, further comprising:
encrypting the electronic circuit file format to an encrypted electronic circuit file format by an encrypting module of the first task processing side; and
providing the encrypted electronic circuit file format to the task assignment side through the network platform for a simulation and trial-run.

9. The tasking method of claim 1, wherein the IC chip comprises a Memory IC chip, a Logic IC chip, a Micro Component IC chip or an Analog IC chip.

10. The tasking method of claim 1, further comprising:
constructing a mechanical structure by a third task processing side in accordance with the task requesting table.

11. The tasking method of claim 1, further comprising:
constructing a case by a fourth task processing side in accordance with the task requesting table.

12. The tasking method of claim 1, further comprising:
constructing a package by a fifth task processing side in accordance with the task requesting table.

13. The tasking method of claim 1, further comprising:
manufacturing the board circuit by a circuit manufacturing side.

14. A computer program product loading and executing the tasking method of claim 1 through a computer.

15. The computer program product of claim 14, wherein the computer program product is stored in a recording media.

16. A tasking system connected to a network platform for manufacturing an electronic unit, the electronic unit comprising at least an IC chip and a board circuit, the IC chip corresponding to an IC program, the tasking system comprising:
a task assignment side connected to the network platform for providing a task requesting table, the task assignment side publicizing the task requesting table to the network platform, wherein the task requesting table is corresponded to the electronic unit requested by the task assignment side;
a first task processing side connected to the network platform, the first task processing side constructing the IC chip in accordance with the task requesting table; and
a second task processing side connected to the network platform, the second task processing side constructing the board circuit in accordance with the task requesting table.

17. The tasking system of claim 16, wherein the IC chip comprises a Memory IC chip, a Logic IC chip, a Micro Component IC chip, or an Analog IC chip.

18. The tasking system of claim 16, further comprising:
a chip manufacturing side connected to the first task processing side for manufacturing the IC chip.

19. The tasking system of claim 16, further comprising:
an assembling module at least connected to the first task processing side and the second task processing side, the assembling module assembling the IC chip and the board circuit in order to form the electronic unit.

20. The tasking system of claim 16, wherein the first task processing side further comprises:
an IC designing module, the IC designing module designing the IC program for the IC chip in accordance with the request of the electronic unit; and
a converting module connected to the IC designing module for converting the IC program to an electronic circuit file format.

21. The tasking system of claim 20, wherein the first task processing side further comprises:
a programming module for programming the electronic circuit file format to a programmable logic chip.

22. The tasking system of claim 21, wherein the programming module programs the electronic circuit file format to the programmable logic chip for verifying the IC program.

23. The tasking system of claim 21, wherein the programmable logic chip comprises a FPGA chip or a CPLD chip.

24. The tasking system of claim 20, the first task processing side further comprising:
an encrypting module for encrypting the electronic circuit file format to an encrypted electronic circuit file format.

25. The tasking system of claim 24, wherein the task assignment side further comprises:
a testing module for simulating and trial-running the encrypted electronic circuit file format.

26. The tasking system of claim 16, further comprising:
a third task processing side connected to the network platform and the assembling module, the third task processing constructing a mechanical structure in accordance with the task requesting table.

27. The tasking system of claim 26, wherein the assembling module is connected to the third task processing side, and assembles the mechanical structure, the IC chip and the corresponded board circuit for forming the electronic unit.

28. The tasking system of claim 16, further comprising:
a fourth task processing side connected to the network platform and the assembling module, the fourth task processing side manufacturing a case in accordance with the task requesting table.

29. The tasking system of claim 28, wherein the assembling module is connected to the fourth task processing side, and assembles the case, the IC chip and the corresponded board circuit for forming the electronic unit.

30. The tasking system of claim 16, further comprising:
a fifth task processing side connected to the network platform, the fifth task processing side manufacturing a package in accordance with the task requesting table; and
a packaging module connected to the fifth task processing side for combining the package and the electronic unit.

31. The tasking system of claim 16, further comprising:
a circuit manufacturing side connected to the second task processing side, the circuit manufacturing side manufacturing the corresponded board circuit.

32. A trading method for a customized electronic unit, the trading method being applied on a network platform, the network platform providing a buyer side and at least a seller side login into the network platform and performing a network trading of the customized electronic unit with at least an IC chip, the trading method comprising:
providing a task requesting table by the buyer side, and publicizing the task requesting table to the network platform, wherein the task requesting table is corresponded to the customized electronic unit;
receiving and applying the task by the first seller side through the network platform in accordance with the task requesting table;
designing an IC program corresponded to the IC chip by the first seller side in accordance with the task requesting table;
uploading a chip function specification according to the IC program to the network platform, wherein the chip function specification has a chip price;
receiving and applying the task by the second buyer side in accordance with the task requesting table if the buyer side accepting the chip price and the chip function specification;
constructing a board circuit by the second buyer side in accordance with the task requesting table;
uploading a circuit function specification of the board circuit to the network platform, wherein the circuit function specification has a circuit price; and
if the buyer side accepting the circuit price and the circuit function specification, the buyer side and the seller side trading on the network platform in accordance with the chip price and the circuit price, and the buyer side obtaining the customized electronic unit.

33. The trading method of claim 32, wherein the IC chip comprises a Memory IC chip, a Logic IC chip, a Micro Component IC chip or an Analog IC chip.

34. The trading method of claim 32, further comprising:
receiving and applying the task by a third seller side in accordance with the task requesting table;
constructing a mechanical structure by the third seller side in accordance with the task requesting table;
uploading a mechanical structure specification to the network platform, wherein the mechanical structure specification has a mechanical structure price; and
if the buyer side accepting the mechanical structure price and the mechanical structure specification, the buyer side and the seller side trading on the network platform in accordance with the mechanical structure price, and the buyer side obtaining the electronic unit with the mechanical structure.

35. The trading method of claim 32, further comprising:
manufacturing the board circuit by a circuit manufacturing module.

36. The trading method of claim 32, further comprising:
receiving and applying the task by a fourth seller side through the network platform in accordance with the task requesting table:
providing a case by the fourth seller side in accordance with the task requesting table;
uploading a case specification to the network platform, wherein the case specification has a case price; and
if the buyer side and the seller side accepting the case price and the case specification, the buyer side and the seller side trading on the network platform in accordance with the case price, and the buyer side obtaining the customized electronic unit with the case.

37. The trading method of claim 32, further comprising:
receiving and applying the task by a fifth seller side through the network platform in accordance with the task requesting table;
providing a package by the fifth seller side in accordance with the task requesting table;
uploading a package specification to the network platform, wherein the package specification has a package price; and
if the buyer side accepting the package price and the package specification, the buyer side and the seller side trading on the network platform in accordance with the package price, and the buyer side obtaining the customized electronic unit with the package.

38. The trading method of claim 32, further comprising:
converting the IC program to an electronic circuit file format by a converting module; and
manufacturing the IC chip from a chip manufacturing module in accordance with the electronic circuit file format.

39. The trading method of claim 38, further comprising:
encrypting the electronic circuit file format to an encrypted electronic circuit file format by an encrypting module of the first seller side; and
providing the encrypted electronic circuit file format through the network platform to the buyer side for a simulation and trial-run.

40. The trading method of claim 32, further comprising:
programming the IC program to a programmable logic chip for performing a verification for the IC program.

41. The trading method of claim 32, wherein the IC program is designed by using a HDL, wherein the HDL comprises a Verilog or a VHDL.

42. A computer program product loading and executing the tasking method of claim 32 through a computer.

43. The computer program product of claim 42, wherein the computer program product is stored in a recording media.

44. A trading system for a customized electronic unit, the trading system being connected to a network platform and providing a network trading for the customized electronic unit, the customized electronic unit comprising at least an IC chip, the IC chip being corresponded to an IC program, the trading system comprising:
a buyer side connected to the network platform for providing a task requesting table and publicizing the task requesting table to the network platform, the task requesting table being corresponded to the customized electronic unit being purchased by the buyer side,
a first seller side connected to the network platform for receiving and applying the task in accordance with the task requesting table, the first seller side comprising:
an IC designing module for designing the IC program of the IC chip in accordance with the task requesting table;
a chip function specification for instructing the function of the IC chip, the chip function specification having a chip price that being a predetermined price of the IC chip of the seller side; and
a first uploading module connected to the network platform for uploading the chip function specification to the network platform;
a second seller side connected to the network platform for receiving and applying the task in accordance with the task requesting table, the second seller side comprising:
a circuit constructing module for constructing a board circuit in accordance with the task requesting table;
a circuit function specification for instructing the function of the board circuit, the circuit function specification having an circuit price that being a predetermined price of the board circuit of the seller side; and
a second uploading module connected to the network platform for uploading the circuit function specification to the network platform; and
a trading module connected to the network platform for performing a trading of the customized electronic unit between the buyer side and the seller side in accordance with the price.

45. The trading system of claim 44, wherein the IC chip comprises a Memory IC chip, a Logic IC chip, a Micro Component IC chip or an Analog IC chip.

46. The trading system of claim 44, wherein the first seller side further comprises:
a converting module connected to the IC designing module for converting the IC program to an electronic circuit file format.

47. The trading system of claim 46, further comprising:
a chip manufacturing module connected to the network platform for manufacturing the IC chip in accordance with the electronic circuit file format.

48. The trading system of claim 46, wherein the first seller side further comprises:
an encrypting module for encrypting the electronic circuit file format to encrypted file format.

49. The trading system of claim 48, wherein the buyer side further comprises:
a testing module for simulating and trial-running the encrypted electronic circuit file format.

50. The trading system of claim 44, wherein the first seller side further comprises:
a programming module for programming the IC program to a programmable logic chip for a verification.

51. The trading system of claim 50, wherein the programmable logic chip comprises a FPGA chip or a CPLD chip.

52. The trading system of claim 44, wherein after the buyer side accepts the prices and the specifications of the seller side, the trading module performs the trading of the customized electronic unit in accordance with the prices.

53. The trading system of claim 44, further comprising:
a task receiving and applying module connected to the network platform for receiving and applying the task.

54. The trading system of claim 44, further comprising:
a third seller side connected to the network platform for receiving and applying the task in accordance with the task requesting table, the third seller side comprising:
a mechanical structure constructing module for constructing a mechanical structure in accordance with the task requesting table;
a mechanical structure specification for instructing the function of the mechanical structure, the mechanical structure specification having an mechanical structure price that being a predetermined price of the mechanical structure of the seller side; and
a third uploading module connected to the network platform for uploading the mechanical structure specification to the network platform.

55. The trading system of claim 44, wherein the second seller side further comprises:
a circuit manufacturing module for manufacturing the board circuit.

56. The trading system of claim 44, further comprising:
a fourth seller side connected to the network platform for receiving and applying the task in accordance with the task requesting table, the fourth seller side comprising:
a case supplying module for providing a case in accordance with the task requesting table;
a case specification for instructing the function of the case, the case specification having a case price that being a predetermined price of the case of the seller side; and
a fourth uploading module connected to the network platform for uploading the case specification to the network platform.

57. The trading system of claim 44, further comprising:
a fifth seller side connected to the network platform for receiving and applying the task in accordance with the task requesting table, the fifth seller side comprising:
a package supplying module for providing a package in accordance with the task requesting table;
a package specification for instructing the function of the package, the package specification having a package price that being a predetermined price of the package of the seller side; and
a fifth uploading module connected to the network platform for uploading the package specification to the network platform.

58. A quality controlling method for trading an electronic unit, the quality controlling method being applied to a network platform, the electronic unit being a customized electronic unit with at least an IC chip corresponded to an IC program, the quality controlling method comprising:
providing a task requesting table by a buyer side, and publicizing the task requesting table to the network platform, wherein the task requesting table is corresponded to the customized electronic unit being purchased by the buyer side;
constructing the customized electronic unit by the seller side in accordance with the task requesting table and providing an estimated finish time;
judging the customized electronic unit if accomplished within the estimated finish time;
if the customized electronic unit fails to be accomplished within the estimated finish time, a manage side lowering a rating of the seller side;
investigating the customized electronic unit by an investigating module of the network platform;
if the customized electronic unit passes the investigation, the investigating module informing the seller side through the network platform that the customized electronic unit has passed the investigation;
uploading a function specification of the accomplished and investigated customized electronic unit by the seller side, the function specification having a trading price; and
the buyer side accepting the function specification and the trading price and trading with the seller side through the network platform for obtaining the customized electronic unit.

59. The quality controlling method of claim 58, wherein if the customized electronic unit fails to pass the investigation, the manage side informs the seller side to perform a modification, or to perform a modification within a specified period, and then performs an investigation again.

60. The quality controlling method of claim 58, further comprising:
charging an investigation fee to the seller side through the investigating module of the network platform.

61. The quality controlling method of claim 58, further comprising:
receiving and applying the task by the seller side in accordance with the task requesting table through the network platform.

62. The quality controlling method of claim 58, further comprising:
charging a publication fee of the task requesting table to the buyer side through the network platform.

63. The quality controlling method of claim 58, wherein if the seller side accomplishes constructing the customized electronic unit within the estimated finish time, the manage side raising the rating of the seller side.

64. The quality controlling method of claim 58, wherein the IC chip comprises a Memory IC chip, a Logic IC chip, a Micro Component IC chip or an Analog IC chip.

65. The quality controlling method of claim 58, wherein constructing the customized electronic unit by the seller side comprises:
designing the IC program by the seller side in accordance with the task requesting table; and
constructing a board circuit by the seller side in accordance with the task requesting table.

66. The quality controlling method of claim 65, wherein constructing the customized electronic unit comprises:
providing a mechanical structure by the seller side in accordance with the task requesting table.

67. The quality controlling method of claim 65, wherein constructing the customized electronic unit comprises:
providing a case by the seller side in accordance with the task requesting Table.

68. The quality controlling method of claim 65, wherein constructing the customized electronic unit comprises:
providing a package by the seller side in accordance with the task requesting table.

69. The quality controlling method of claim 65, further comprising:
programming the IC program to a programmable logic chip in order to verify the IC program.

70. The quality controlling method of claim 65, further comprising:
converting the IC program to an electronic circuit file format in accordance with the task requesting table; and
manufacturing the IC chip by the seller side in accordance with the electronic circuit file format.

71. The quality controlling method of claim 70, further comprising:
encrypting the electronic circuit file format to an encrypted electronic circuit file format.

72. The quality controlling method of claim 71, wherein the encrypted electronic circuit file format is provided to the buyer side for a simulation and trial-run.

73. The quality controlling method of claim 58, wherein the IC program is designed by using a HDL, wherein the HDL comprises a Verilog or a VHDL.

74. A computer program product, which loading and executing the quality controlling method of claim 58 through a computer.

75. The computer program product of claim 74, wherein the computer product is stored in a recording media.

76. A quality controlling system for trading an electronic unit, the quality controlling system being connected to a network platform and the electronic unit being a customized electronic unit with at least an IC chip corresponded to an IC program, the quality controlling system comprising:
a buyer side connected to the network platform for providing and publicizing a task requesting table on the network platform, wherein the task requesting table is corresponded to the customized electronic unit being purchased by the buyer side;
a seller side connected to the network platform, the seller side with a rating comprising:
a customized electronic unit constructing module for constructing the customized electronic unit in accordance with the task requesting table; and
a function specification for the customized electronic unit and the function specification having a trading price,
a time controlling module connected to the network platform, the time controlling module having an estimated finish time for the customized electronic unit, the seller side assigning the estimated finish time by the time controlling module, and the time controlling module judging if constructing the customized electronic unit being finished or not within the estimated finish time;
a manage side connected to the network platform the manage side raising or lowering the rating of the seller side according whether constructing the customized electronic unit being finished within the estimated finish time or not;
an investigating module connected to the network platform, the investigating module investigating the customized electronic unit and judging if the customized electronic unit passing the investigation or not, if the customized electronic unit passing the investigation, the investigating module informs the seller side through the network platform; and
a trading module connected to the network platform, if the buyer side accepting the function specification and the trading price, the buyer side trading with the seller side through the network platform according to the trading price and the buyer side obtaining the customized electronic unit.

77. The quality controlling system of claim 76, wherein the IC chip comprises a Memory IC chip, a Logic IC chip, a Micro Component IC chip or an Analog IC chip.

78. The quality controlling method of claim 76, wherein the seller side comprises:
a task receiving and applying module connected to the network platform, the seller side receiving and applying the task in accordance with the task requesting table.

79. The quality controlling system of claim 76, wherein the buyer side comprises:
a testing module for simulating and trial-running the customized electronic unit.

80. The quality controlling system of claim 76, wherein constructing the customized electronic unit by the seller side comprises designing the IC program and manufacturing the IC chip, and the IC chip is manufactured according to the IC program.

81. The quality controlling system of claim 80, further comprising:
programming the IC program to a programmable logic chip in order to verify the IC program.

82. The quality controlling system of claim 81, wherein the programmable logic chip comprises a FPGA chip or a CPLD chip.
